(19) United States
(12) Patent Application Publication
(10) Pub. No.: US 2009/0059490 A1
(43) Pub. Date: Mar. 5, 2009

(54) ELECTRONIC APPARATUS

(75) Inventor: Keizo Oogami, Ome-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/200,694

(22) Filed: Aug. 28, 2008

(30) Foreign Application Priority Data
Aug. 31, 2007 (JP) 2007-225885

(51) Int. Cl. H05K 5/00

(52) U.S. Cl. 361/679.55; 361/679.02

(57) ABSTRACT

According to one embodiment, an electronic apparatus is provided with a housing and a display device contained in the housing and including a display screen. The housing includes a mask section with an opening part through which the display screen is exposed to the outside and a cover section situated on the opposite side of the display device from the mask section and combined with the mask section to form the housing. At least a part of the cover section is molded integrally with the mask section. The housing includes a hinge part provided between the mask section and the part of the cover section molded integrally with the mask section. The hinge part is foldable between a first state in which the mask section is opposed to the cover section and a second state in which the mask section is open with respect to the cover section.

### CROSS-REFERENCE TO RELATED APPLICATIONS

This application is based upon and claims the benefit of priority from Japanese Patent Application No. 2007-225885, filed Aug. 31, 2007, the entire contents of which are incorporated herein by reference.

### BACKGROUND

1. Field

One embodiment of the invention relates to an electronic apparatus provided with a housing.

2. Description of the Related Art

An electronic apparatus, such as a portable computer, is provided with a housing that contains a display device. Many housings include a mask section formed with an opening part through which a display screen of the display device is exposed to the outside and a cover section opposed to the display device on the opposite side thereof from the mask section. The mask and cover sections are formed separately from each other and are combined to form the housing after the display device and the like are mounted in place.

An information processing apparatus with an antenna is disclosed in Jpn. Pat. Appln. KOKAI Publication No. 2002-32150. In this information processing apparatus, the antenna is contained in a metal housing, and a cut-off part is provided at that part of the housing in which the antenna is located. The cut-off part is covered by an antenna cover that is made of a nonmetal, e.g., a plastic material. According to this arrangement, the antenna is improved in wave transmission and reception characteristics.

In general, fixing components, such as screws, are used to assemble a housing. If the number of such essential fixing components is increased, however, the assemblability of the housing may possibly be reduced.

If a part (e.g., antenna cover) of the cover section is formed separately from another part, as in the apparatus described in the aforesaid patent document, the number of essential fixing components for the assembly of the housing is great.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary perspective view of a portable computer according to a first embodiment of the invention;

FIG. 2 is an exemplary perspective view of the portable computer shown in FIG. 1;

FIG. 3 is an exemplary sectional view of a display unit shown in FIG. 1;

FIG. 4 is an exemplary sectional view enlargedly showing a region of the display unit encircled by dash-dotted line F4 in FIG. 3;

FIG. 5 is an exemplary sectional view showing a state in which a hinge part shown in FIG. 4 is open; and

FIG. 6 is an exemplary perspective view of a display unit according to a second embodiment of the invention.

### DETAILED DESCRIPTION

Various embodiments according to the invention will be described hereinafter with reference to the accompanying drawings. In general, according to one embodiment of the invention, an electronic apparatus is provided with a housing and a display device contained in the housing and including a display screen. The housing includes a mask section provided with an opening part through which the display screen is exposed to the outside of the housing and a cover section situated on the opposite side of the display device from the mask section and combined with the mask section to form the housing. At least a part of the cover section is molded integrally with the mask section. The housing includes a hinge part which is provided between the mask section and the part of the cover section molded integrally with the mask section. The hinge part is foldable between a first state in which the mask section is opposed to the cover section and a second state in which the mask section is open with respect to the cover section.

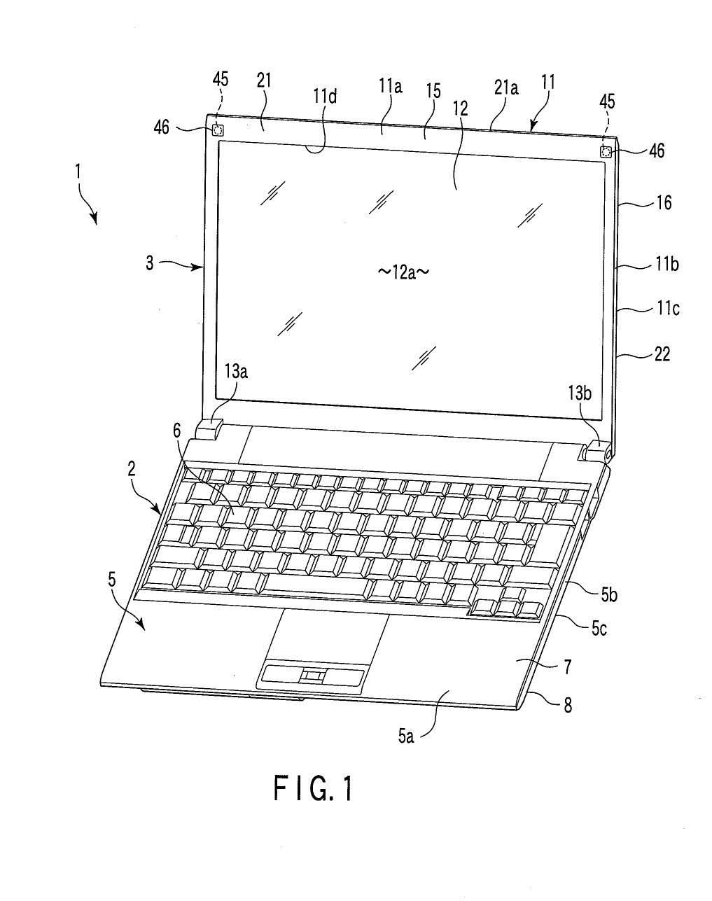

An embodiment of the present invention applied to a portable computer will now be described with reference to the accompanying drawings. FIGS. 1 to 5 show a portable computer 1 as an electronic apparatus according to a first embodiment of the invention. FIG. 1 shows an outline of the portable computer 1. As shown in FIG. 1, the portable computer 1 is provided with a body 2 and a display unit 3.

The body 2 is provided with a box-like body housing 5. The body housing 5 includes a top wall 5a, a peripheral wall 5b, and a bottom wall 5c. The top wall 5a supports a keyboard 6. The body housing 5 is provided with a housing cover 7, which includes the top wall 5a and a part of the peripheral wall 5b, and a housing base 8, which includes the bottom wall 5c and a part of the peripheral wall 5b. The housing cover 7 is combined with the housing base 8 so that a storage space for a main board (not shown), for example, is defined between the cover 7 and the base 8.

As shown in FIG. 1, the display unit 3 is provided with a box-like display housing 11 and a display device 12 contained therein. The display housing 11 is an example of a housing according to the present invention, and it will be referred to simply as the housing 11 hereinafter. While an example of the display device 12 is a liquid crystal display module, the display device according to the present invention is not limited to it. Alternatively, the device 12 may be any of various display devices, such as a plasma display, organic electroluminescent display, etc. The display device 12 includes a display screen 12a on one surface thereof.

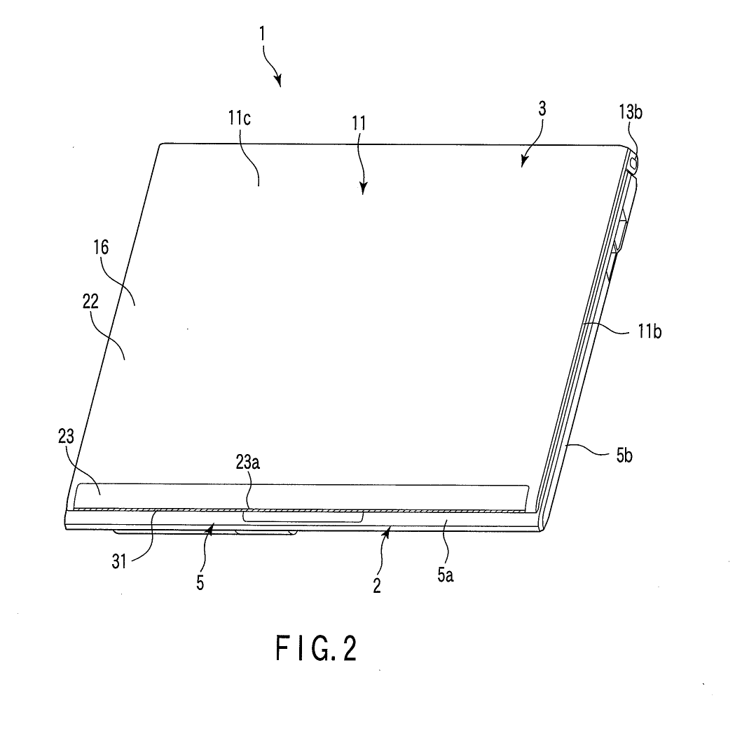

The display unit 3 is supported on the rear end portion of the body housing 5 by a pair of body hinge parts 13a and 13b. Thus, the display unit 3 is swingable between a closed position (see FIG. 2) in which it is leveled to cover the top wall 5a of the body housing 5 from above and an open position (see FIG. 1) in which it is raised so that the top wall 5a is exposed.

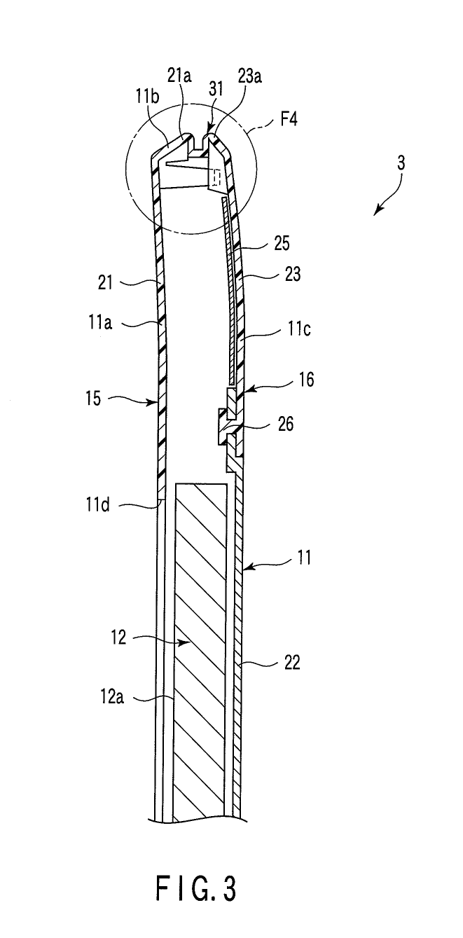

FIG. 3 is a sectional view of the display unit 3. As shown in FIGS. 1 to 3, the housing 11 of the display unit 3 includes a front wall 11a located in front of the display device 12 (that is, in the user side), a rear wall 11c located behind the display device 12, and a peripheral wall 11b that connects the respective peripheral edge portions of the front and rear walls 11a and 11c. The front wall 11a is provided with an opening part 11d through which the display screen 12a is exposed to the outside of the housing 11.

The housing 11 is provided with a mask section 15, which includes the front wall 11a and a part of the peripheral wall 11b, and a cover section 16, which includes the rear wall 11c and a part of the peripheral wall 11b and is situated on the opposite side of the display device 12 from the mask section 15. The housing 11 is formed by combining the mask section 15 and the cover section 16.

In the present embodiment, the housing 11 is provided with an LCD mask 21, which includes the front wall 11a and a part of the peripheral wall 11b, an LCD cover 22, which includes a part of the peripheral wall 11b and a part of the rear wall 11c, and an antenna cover 23, which includes a part of the peripheral wall 11b and a part of the rear wall 11c. Thus, in the present embodiment, the LCD mask 21 forms an example of the mask section 15. Further, the LCD cover 22 and the antenna cover 23 form an example of the cover section 16 in conjunction with each other. In other words, the antenna cover 23 is a part of the cover section 16. Furthermore, the LCD cover 22 occupies most of that part of the cover section 16. The LCD cover 22 is situated off the antenna cover 23 and corresponds to an example of “another part” of the cover portion according to the present invention.

As shown in FIG. 3, the housing 11 contains an antenna 25. The antenna 25 according to the present invention is not limited to any specific type, but may be selected from various specific examples corresponding to, for example, Bluetooth (trademark), wireless LAN, wireless WAN, WiMAX, UWB, GPS, or cellular telephony.

The antenna cover 23 is provided in a region in which the antenna 25 is mounted and faces the antenna 25. As shown in FIGS. 2 and 3, the antenna cover 23 is located at an end portion of the housing 11 opposite from that one which faces the body hinge parts 13a and 13b. That is, the antenna cover 23 is provided in a region that forms an end portion of the housing 11 which is to be an upper end portion when the display unit 3 is in the said open position. The antenna cover 23 extends in the width direction of the housing 11 along one of circumferential edges of the housing 11 at the end portion of the housing 11.

The antenna cover 23 is molded separately from the LCD cover 22. An example of the LCD cover 22 is made of a metal, such as a magnesium alloy. The antenna cover 23 is made of a nonmetal, e.g., a plastic material. By means of this antenna cover 23, the antenna 25 may satisfactorily serve for transmission and reception even if the LCD cover 22 is metallic, for example.

The LCD cover 22 need not always be metallic but may alternatively be, for example, plastic. Further, an example of the LCD mask 21 is plastic.

As shown in FIG. 3, the antenna cover 23 is provided with a welded joint 26 that is welded to the LCD cover 22. The antenna cover 23 is fixed to the LCD cover 22 with the welded joint 26 welded to the LCD cover.

On the other hand, the antenna cover 23 is molded integrally with the LCD mask 21. Further, a hinge part 31 is provided between the cover 23 and the mask 21. The hinge part 31 is foldable between a first state (see two-dot chain lines in FIG. 5) in which the mask section 15 is opposed to the cover section 16 and a second state (see solid lines in FIG. 5) in which the mask section 15 is open with respect to the cover section 16. A folded edge at the hinge part 31 forms a part of the circumferential edges of the housing 11.

The hinge part 31 is deformable to a position where the mask section 15 is open at an angle of 180° with respect to the cover section 16, for example. Thus, the LCD mask 21 and the antenna cover 23 may be aligned in a straight line with each other.

The material of the LCD mask 21 and the antenna cover 23 that are molded integrally with each other may be, for example, polypropylene as a material suited for the aforesaid hinge function. However, the material of the mask 21 and the cover 23 is not limited to polypropylene, but is only expected to with stand, for example, one or more folding actions and may be selected from a wide variety of materials.

In FIG. 2, the hinge part 31 is hatched for ease of illustration. As shown in FIG. 2, the hinge part 31 linearly extends along the boundary between the LCD mask 21 and the antenna cover 23. Specifically, the LCD mask 21 and the antenna cover 23 are each formed to be rectangular. The hinge part 31 is provided between one side 21a (see FIG. 1) of the LCD mask 21 and one side 23a of the antenna cover 23 that adjoin each other. The hinge part 31 is disposed to span from one end of the antenna cover 23 to the other, for example. However, it is necessary only that the hinge part 31 be disposed in at least a part of the region between the two ends of the antenna cover 23.

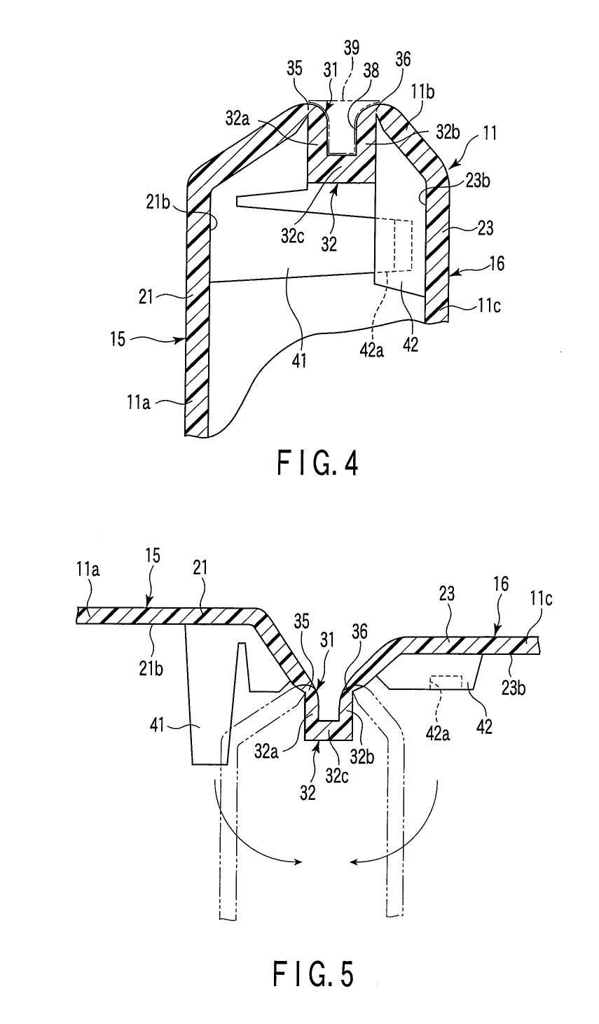

As shown in FIG. 4, the hinge part 31 is provided with a beam portion 32 that projects into the housing 11. The beam portion 32 extends along the extension of the hinge part 31 so as to cover the overall length of the hinge part 31, for example. Alternatively, however, the beam portion 32 may be disposed covering only a part of the length of the hinge part 31. Further, the beam portion 32 may be formed protruding from the hinge part 31 to the outside of the housing 11.

The beam portion 32 is arched, for example. Specifically, as shown in FIG. 4, the beam portion 32 includes first and second ribs 32a and 32b and a connecting portion 32c. The first rib 32a projects into the housing 11 from an edge portion of the beam portion 32 that faces the LCD mask 21 and extends along the extension of the beam portion 32. The second rib 32b projects into the housing 11 from an edge portion of the beam portion 32 that faces the antenna cover 23 and extends along the extension of the beam portion 32. The connecting portion 32c bridges respective projecting ends of the first and second ribs 32a and 32b.

The thickness of the connecting portion 32c is greater than, for example, the basic thickness of the LCD cover 22. The basic thickness of a member is a thickness that, among others, is most commonly used for the member. The basic thickness of the LCD cover 22 is, for example, less than 1.0 mm, and more specifically, ranges from 0.5 to 0.8 mm, for example. On the other hand, the connecting portion 32c has a thickness of 1.0 mm, for example. The beam portion 32 is not limited to an arch, but it may be of any shape that ensures a higher section modulus than a flat shape. Thus, various other shapes, such as an H-, L- or T-shape, may be suitably used for the beam portion 32.

On the other hand, the hinge part 31 includes first and second thin-walled portions 35 and 36. The first thin-walled portion 35 is provided between the beam portion 32 and the LCD mask 21. Further, the second thin-walled portion 36 is provided between the beam portion 32 and the antenna cover 23. The first and second thin-walled portions 35 and 36 are those regions of the hinge part 31 which are actually folded. Therefore, their thicknesses are smaller than the basic thickness of the LCD cover 22, for example. As the first and second thin-walled portions 35 and 36 are bent or stretched, the hinge part 31 is deformed between the said first and second states.

As shown in FIG. 4, moreover, the hinge part 31 includes the first and second ribs 32a and 32b and the connecting portion 32c, thereby forming a recess 38 in the outer surface of the housing 11. If necessary, a rubber facing 39 as an example of a facing member is attached to the recess 38 of the hinge part 31, as indicated by two-dot chain line in FIG. 4.

As shown in FIG. 5, an engaging lug 41 as a first engaging portion is provided on an inner wall surface 21b of the LCD mask 21. A receiving rib 42 as a second engaging portion is provided on an inner wall surface 23b of the antenna cover 23. The receiving rib 42 is provided with a notch 42a that configured to engage with the engaging lug 41. When the housing 11 is assembled, as shown in FIG. 4, the engaging lug 41 is fitted into the notch 42a of the receiving rib 42, whereby the LCD mask 21 and the antenna cover 23 are firmly fixed together.

The engaging lug 41 and the receiving rib 42 are provided in each of a plurality of spots, for example. It is to be understood that the LCD mask 21 and the antenna cover 23 may alternatively be provided with the receiving rib 42 and the engaging lug 41, respectively.

As shown in FIG. 1, screws 45 for fixing the LCD mask 21 to the LCD cover 22 and facing members 46 that conceal the screws 45 from outside the housing 11 are disposed at the transversely opposite end portions of the housing 11. On the other hand, there are no screws for fixing the antenna cover 23 to the LCD cover 22 or the LCD mask 21.

The following is a description of a manufacturing method for the display unit 3.

The antenna cover 23 is molded integrally with the LCD mask 21 by, for example, injection molding in such a manner that it is open with respect to the mask 21, that is, the cover 23 and the mask 21 are aligned in a straight line with each other (see solid lines in FIG. 5). The antenna cover 23 that is molded integrally with the LCD mask 21 is fixed to the LCD cover 22 by welding. Thus, a subassembly is formed including the LCD mask 21, the LCD cover 22 and the antenna cover 23.

In an assembly process for the portable computer 1, the display device 12 and other components are mounted inside the LCD cover 22 with the LCD mask 21 open with respect to the cover 22, and the antenna 25 is mounted inside the antenna cover 23. After these components are mounted, the LCD mask 21 is folded around the hinge part 31 with respect to the antenna cover 23 and combined with the LCD cover 22. As the mask 21 is combined with the cover 22, the engaging lug 41 is inserted into the notch 42a of the receiving rib 42 so that the mask 21 and the antenna cover 23 are firmly fixed together. After the LCD mask 21 and the LCD cover 22 are combined, they are fixed to each other with the screws 45. Thereupon, assembling the display unit 3 is completed.

According to the portable computer 1 constructed in this manner, the number of essential fixing components, such as screws, is capable of being reduced. Specifically, if at least a part (i.e., the antenna cover 23 in the present embodiment) of the cover section 16 is molded integrally with the mask section 15, fixing of the mask section 15 to the cover section 16 can be secured to some degree at the junction between the sections 15 and 16. Thus, the fixing components for fixing the mask section 15 to the cover section 16 can be reduced in number.

If the foldable hinge part 31 is provided between the mask section 15 and that region of the cover section 16 which is molded integrally with the mask section 15, moreover, the mask section 15 and the integral region of the cover section 16 can be molded without regard to the shape of the completed housing 11. More specifically, it is difficult to mold the mask section 15 and the cover section 16 in completed forms, since they are configured to face the display device 12 from opposite sides. If the hinge part 31 is provided so that it is foldable between the first state in which the mask section 15 is opposed to the cover section 16 and the second state in which the mask section 15 is open with respect to the cover section 16, however, the mask section 15 and the part of the cover section 16 is capable of being integrally molded in the second state that is suited for molding.

Thus, the provision of the hinge part 31 enables at least a part of the cover section 16 to be molded integrally with the mask section 15 at low cost, and greatly contributes to a reduction in the number of fixing components for fixing the sections 15 and 16.

If the fixing components, especially screws that require a mounting operation involving rotation, are capable of being reduced in number, the assembly work can be simplified, so that the assemblability of the portable computer 1 is capable of being improved considerably. If a member, such as the antenna cover 23, provided separately from the LCD cover 22 is molded integrally with the mask section 15, moreover, the number of components used in the housing 11 is capable of being reduced.

If the hinge part 31 linearly extends along the boundary between the cover section 16 and the mask section 15, the sections 16 and 15 connect with each other over a specific area, so that they can be said to be relatively firmly connected in advance. Thus, the number of fixing components for fixing the mask section 15 to the cover section 16 is capable of being further reduced.

If the hinge part 31 includes the beam portion 32 that projects into the housing 11, the section modulus of the region between the mask section 15 and the cover section 16 increases, so that the rigidity of the housing 11 becomes higher than in the case where the LCD mask 21 and the antenna cover 23 are separate from each other. If the rigidity of the housing 11 increases, the necessity of firmly fixing the mask section 15 to the cover section 16 is reduced, so that the number of fixing components for the mask and cover sections 15 and 16 is capable of being reduced additionally.

If the apparatus is provided with the antenna 25 and the antenna cover 23, for example, a component that contains a metal, such as the display device 12, may not be located within a predetermined distance of the antenna 25. Therefore, a dead space is easily created around the antenna cover 23 in the housing 11. The beam portion 32 of the present embodiment is provided by effectively utilizing this dead space. Thus, also by the use of the beam portion 32, the small portable computer 1 is capable of being provided without increasing the size of the housing 11.

If the beam portion 32 extends along the extension of the hinge part 31, moreover, then it means that one beam extends along the width of the housing 11, so that the rigidity of the housing 11 is increased. If the beam portion 32 includes the first and second ribs 32a and 32b and the connecting portion 32c, furthermore, the rigidity of the housing 11 is higher than in the case where the beam portion 32 is formed of only one rib, for example. The aforementioned effect is produced by the increase in rigidity of the housing 11.

As described above, a dead space is easily created around the antenna cover 23 in the housing 11. The housing 11 is also capable of being further increased in rigidity without becoming large-sized by making the thickness of the connecting portion 32c greater than the basic thickness of the cover section 16.

The upper end portion of the housing 11 on which the antenna cover 23 is disposed should preferably be rigid enough, since it is often handled by a user who opens or closes the display unit 3 with respect to the body 2. If the antenna cover 23 is provided separately from the LCD mask 21 and the LCD cover 22, however, the rigidity of the upper end portion of the housing 11 is reduced inevitably.

According to the present embodiment, on the other hand, the antenna cover 23 is molded integrally with the LCD mask 21, and one beam portion 32 passes along the boundary between the cover 23 and the mask 21. Thus, satisfactory rigidity is capable of being secured for the upper end portion of the housing 11 on which the antenna cover 23 is disposed.

If the thin-walled portions 35 and 36 are provided between the beam portion 32 and the mask section 15 and between the beam portion 32 and the cover section 16, respectively, the beam portion 32 can enhance the rigidity of the hinge part 31, and the thin-walled portions 35 and 36 can ensure the function of the hinge part 31.

The hinge part 31 is connected to the housing 11 by the thin-walled portion that is plastic. Supposedly therefore, the housing 11 is induced to bulge when the hinge part 31 is folded. If the apparatus is provided with the engaging lug 41 and the receiving rib 42, the housing 11 is capable of being prevented from bulging by engaging the engaging lug 41 with the receiving rib 42 as the housing 11 is assembled.

If the LCD cover 22 is metallic, it is inevitable that the nonmetallic antenna cover 23 be formed separately from the LCD cover 22. Also in the portable computer 1 according to the present embodiment arranged in this manner, however, the fixing components and other essential components is capable of being reduced in number, and the rigidity of the housing 11 may be increased.

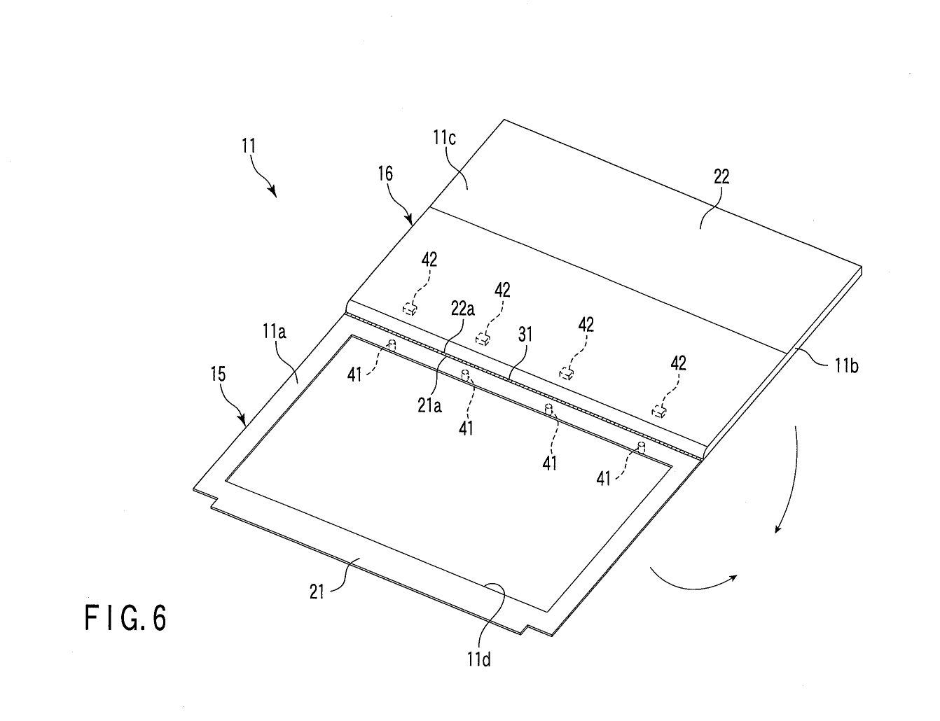

A portable computer 1 as an electronic apparatus according to a second embodiment of the invention will now be described with reference to FIG. 6. Like reference numbers are used to designate structures of the portable computers of the first and second embodiments having the same or similar functions, and a description of those structures is omitted. The second embodiment differs from the first embodiment in the shape of the housing 11 of the display unit 3, and the basic configuration of the portable computer 1 of the second embodiment is the same as that of the first embodiment.

The portable computer 1 is provided with a body 2 and the display unit 3. The display unit 3 is provided with a housing 11 and a display device 12 contained therein. The housing 11 includes a mask section 15 and a cover section 16.

In the present embodiment, the housing 11 is provided with an LCD mask 21, which includes a front wall 11a and a part of a peripheral wall 11b, and an LCD cover 22, which includes a rear wall 11c and a part of the peripheral wall 11b. The LCD mask 21 forms an example of the mask section 15. Further, the LCD cover 22 forms an example of the cover section 16. The present embodiment is not provided with an antenna cover.

In the present embodiment, the LCD mask 21 is molded integrally with the LCD cover 22. In other words, the mask section 15 is molded integrally with the entire cover section 16. A hinge part 31 having the same construction as that of the first embodiment is provided between the LCD mask 21 and the LCD cover 22. Specifically, the hinge part 31 includes a beam portion 32 and first and second thin-walled portions 35 and 36. The hinge part 31 is foldable between a first state in which the LCD mask 21 is opposed to the LCD cover 22 and a second state in which the mask 21 is open with respect to the cover 22.

As shown in FIG. 6, the hinge part 31 linearly extends along the boundary between the LCD mask 21 and the LCD cover 22. Specifically, the mask 21 and the cover 22 are each formed to be rectangular. The hinge part 31 is provided between one side 21a of the mask 21 and one side 22a of the cover 22 that adjoin each other. The hinge part 31 is disposed to span from one end of the LCD cover 22 to the other, for example. However, it is necessary only that the hinge part 31 be disposed in at least a part of the region between the two ends of the LCD cover 22.

According to the portable computer 1 constructed in this manner, the number of essential fixing components, such as screws, is capable of being reduced. Specifically, if at least a part (i.e., the LCD cover 22 that forms the entire cover section 16 in the present embodiment) of the cover section 16 is molded integrally with the mask section 15, fixing of the mask section 15 to the cover section 16 is capable of being secured to some degree at the junction between the sections 15 and 16. Thus, the fixing components for fixing the mask section 15 to the cover section 16 are capable of being reduced in number. If the apparatus is provided with the hinge part 31, moreover, the cover section 16 and the mask section 15 is capable of being molded without regard to the shape of the completed housing 11.

Although the portable computers 1 according to the first and second embodiments of the present invention have been described herein, the invention is not limited to these embodiments. The structures according to the embodiments may be suitably combined in practical use.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic apparatus comprising:
a housing; and
a display device contained in the housing and including a display screen,
wherein the housing comprises a mask provided with an opening portion through which the display screen is exposed to the outside of the housing and a cover situated on the opposite side of the display device from the mask and combined with the mask to form the housing;
at least a portion of the cover is molded integrally with the mask; and
the housing further comprises a hinge provided between the mask and the portion of the cover, the hinge being foldable between a first state in which the mask is opposed to the cover and a second state in which the mask is open to the cover.

2. The electronic apparatus of claim 1, wherein the hinge is configured to linearly extend along the boundary between the cover and the mask.

3. The electronic apparatus of claim 2, wherein the hinge comprises a beam portion projecting into the housing and extending along the extension of the hinge.

4. The electronic apparatus of claim 3, wherein the hinge comprises a first thin-walled portion between the beam portion and the mask and a second thin-walled portion between the beam portion and the cover, respectively, the thickness of each thin-walled portion being smaller than the thickness of the cover.

5. The electronic apparatus of claim 3, wherein the beam portion comprises a first rib projecting into the housing from an edge of the beam portion configured to face the mask and extending along the extension of the beam portion, a second rib projecting into the housing from an edge of the beam portion configured to face the cover and extending along the extension of the beam portion, and a connecting portion configured to bridge between projecting ends of the first rib and the second rib.

6. The electronic apparatus of claim 5, wherein the thickness of the connecting portion is greater than the thickness of the cover.

7. The electronic apparatus of claim 1, further comprising:
a first engaging portion provided on the mask, and a second engaging portion provided on the cover and configured to engage with the first engaging portion when the housing is assembled.

8. The electronic apparatus of claim 1, further comprising:
an antenna in the housing;
wherein the cover comprises an antenna cover provided in a region in which the antenna is mounted, the antenna cover being molded separately from the rest of the cover and integrally with the mask.

9. The electronic apparatus of claim 8, wherein the rest of the cover is made of metal.
